(19) United States
(12) Patent Application Publication
(10) Pub. No.: US 2011/0117503 A1
(43) Pub. Date: May 19, 2011

(54) EXPOSURE APPARATUS AND DEVICE FABRICATION METHOD

(75) Inventor: Takanori UEMURA, Utsunomiya-shi (JP)

(73) Assignee: CANON KABUSHIKI KAISHA, Tokyo (JP)

(21) Appl. No.: 12/948,647

(22) Filed: Nov. 17, 2010

(30) Foreign Application Priority Data
Nov. 17, 2009 (JP) 2009-262370

(51) Int. Cl. G03F 7/20; G03B 27/54

(52) U.S. Cl. 430/322; 355/67

(57) ABSTRACT

The present invention provides an exposure apparatus including an illumination optical system, the illumination optical system includes a mirror array optical element including a plurality of mirror elements having reflecting surfaces which reflect light from a light source, the plurality of mirror elements having angles that can be independently controlled with respect to the light from the light source, a first optical system configured to guide the light from the light source to the mirror array optical element, and receive light reflected by a predetermined mirror element, an angle of which is controlled to guide the light reflected by the reflecting surface to the reticle, a second optical system which is present on a side of the light source with respect to the first optical system, and a third optical system which is present on a side of the reticle with respect to the first optical system.

### BACKGROUND OF THE INVENTION

1. Field of the Invention

The present invention relates to an exposure apparatus and a device fabrication method.

2. Description of the Related Art

To fabricate high-performance semiconductor devices at low cost, patterns (circuit patterns) to be transferred onto substrates such as wafers are becoming finer. In recent years, to ensure a large process margin for fine patterns, a technique of optimizing the pattern of a reticle (mask) and the effective light source (the angular distribution of light which illuminates the reticle or the light intensity distribution on the pupil plane) is attracting a great deal of attention. This technique is generally called SMO (Source Mask Optimization). The effective light source optimized by SMO often has a shape more complex than both a circular shape and an annular shape.

Under the circumstance, U.S. Pat. No. 6,563,566, Japanese Patent Laid-Open No. 11-3849, and U.S. Patent Publication No. 2006/0087634 each propose a technique of forming an effective light source, which is optimized by SMO and has a complex shape, by inserting a mirror array optical element into an illumination optical system that illuminates a reticle. The mirror array optical element includes a plurality of mirror elements, the tilts of which can be independently controlled.

In U.S. Pat. No. 6,563,566, each mirror element has a size of about 1 mm, and can be tilted by a predetermined angle with respect to two axes. However, it is difficult to manufacture a mirror array optical element including mirror elements that can be tilted by a predetermined angle with respect to two axes. It is also difficult to increase the number of mirror elements that constitute the mirror array optical element. Hence, the mirror array optical element includes only about 500 mirror elements in U.S. Pat. No. 6,563,566, so, in practice, it is difficult to form an effective light source with a complex shape optimized by SMO.

Japanese Patent Laid-Open No. 11-3849 and U.S. Patent Publication No. 2006/0087634 each propose a mirror array optical element including mirror elements which can be controlled (switched) to two states: an “on state” and an “off state”. Because the angles of the mirror elements need only be controlled between an “on state” and an “off state”, this mirror array element is relatively easy to manufacture, and a large number of mirror elements can then be densely arranged. Also, in U.S. Patent Publication No. 2006/0087634, an effective light source with a complex shape can be formed while suppressing a decrease in illumination efficiency by roughly forming a shape of an effective light source using a computer generated hologram (CGH), and adjusting a fine shape of the effective light source using a mirror array optical element.

Since a mirror array optical element is a reflective optical element, incident light (light which enters the mirror array optical element) and exit light (light reflected by the mirror array optical element) must be separated from each other. In each of Japanese Patent Laid-Open No. 11-3849 and U.S. Patent Publication No. 2006/0087634, the mirror array optical element is tilted with respect to the optical axis of the illumination optical system to deflect the light, thereby separating the incident light and exit light from each other.

However, the inventor of the present invention conducted a close examination, and obtained results which reveal that in the prior arts an asymmetric blur occurs in the effective light source (i.e., its light intensity distribution along the x-axis and that along the y-axis become different from each other), and this adversely affects the exposure performance.

The fact that an asymmetric blur occurs in an effective light source formed in the illumination optical system will be described in detail below with reference to FIGS. 7A to 7E. FIG. 7A is a schematic view showing the arrangement of a conventional illumination optical system. In the illumination optical system shown in FIG. 7A, a mirror array optical element 1010 is tilted with respect to an incident-side optical axis AXa and an exit-side optical axis AXb to separate incident light beams La (incident light beams La1 and La2) and exit light beams Lb (exit light beams Lb1 and Lb2) from each other.

Light beams reflected by a plurality of mirror elements 1012, respectively, included in the mirror array optical element 1010 are guided to a microlens array 1030 (its incident surface 1032) via a relay lens 1020. At this time, because the mirror array optical element 1010 is tilted with respect to the optical axes AXa and AXb, the exit light beams Lb1 and Lb2 have different focal positions. More specifically, the exit light beam Lb1 has a focal position on the light source side (in the −z-axis direction) with respect to the incident surface 1032, and the exit light beam Lb2 has a focal position on the reticle side (in the +z-axis direction) with respect to the incident surface 1032.

FIG. 7B is a view showing the outer appearance of the mirror array optical element 1010, in which the mirror elements 1012 are independently controlled to an “on state” or an “off state” to form an effective light source with a predetermined shape. Referring to FIG. 7B, reference numeral 1012a denotes a mirror element controlled to an “on state”; and 1012b, a mirror element controlled to an “off state”, and the mirror array optical element 1010 forms an annular effective light source.

FIG. 7C is a view showing a light intensity distribution formed on the incident surface 1032 of the microlens array 1030 when the mirror array optical element 1010 is in the state shown in FIG. 7B. As described earlier, the focal position of the exit light beam Lb from the mirror array optical element 1010 changes in accordance with its position in the y-axis direction, so the light intensity distribution shown in FIG. 7C deteriorates from an ideal annular shape and has a blur along the y-axis. Referring to FIG. 7C, the light intensity is constant in a region Ra, and the light intensity gradually attenuates in a region Rb.

FIGS. 7D and 7E are sectional views taken along lines α-α′ and β-β′, respectively, in the light intensity distribution shown in FIG. 7C. The focal position of the exit light beam Lb from the mirror array optical element 1010 remains the same regardless of its position in the x-axis direction, so the light intensity distribution formed by the exit light beam Lb has no blur along the x-axis and has a rectangular cross-section along the x-axis, as shown in FIG. 7D. In contrast, the focal position of the exit light beam Lb changes in accordance with its position in the y-axis direction, so the light intensity distribution formed by the exit light beam Lb has a blur along the y-axis and has a trapezoidal cross-section along the y-axis, as shown in FIG. 7E. In this manner, in the prior arts, asymmetry occurs in the effective light source in the x- and y-axis directions, and this adversely affects the exposure performance.

### SUMMARY OF THE INVENTION

The present invention provides a technique which can form a light intensity distribution (effective light source) with high accuracy even if a mirror array optical element is used.

According to one aspect of the present invention, there is provided an exposure apparatus including an illumination optical system configured to illuminate a reticle with light from a light source, and a projection optical system configured to project a pattern of the reticle onto a substrate, the illumination optical system including a mirror array optical element including a plurality of mirror elements having reflecting surfaces which reflect the light from the light source, the plurality of mirror elements having angles that can be independently controlled with respect to the light from the light source, a first optical system configured to guide the light from the light source to the mirror array optical element, and receive light reflected by a predetermined mirror element, an angle of which is controlled to guide the light reflected by the reflecting surface to the reticle, among the plurality of mirror elements, a second optical system which is present on a side of the light source with respect to the first optical system, and is configured to guide the light from the light source to the first optical system, and a third optical system which is present on a side of the reticle with respect to the first optical system, and is configured to receive the light from the first optical system, wherein an exit-side optical axis of the second optical system and an incident-side optical axis of the third optical system are parallel to an optical axis of the predetermined mirror element, and are spaced apart from the optical axis of the predetermined mirror element, and a reflecting surface of the predetermined mirror element is perpendicular to the exit-side optical axis of the second optical system and the incident-side optical axis of the third optical system.

Further features of the present invention will become apparent from the following description of exemplary embodiments with reference to the attached drawings.

### BRIEF DESCRIPTION OF THE DRAWINGS

FIG. 1 is a view showing the arrangement of an exposure apparatus in the first embodiment of the present invention.

FIGS. 2A and 2B are views for explaining an optical system from a deflecting mirror to a microlens array in an illumination optical system of the exposure apparatus shown in FIG. 1.

FIGS. 3A to 3F are views for explaining an example of an effective light source formed by the illumination optical system of the exposure apparatus shown in FIG. 1.

FIGS. 4A to 4F are views for explaining other examples of an effective light source formed by the illumination optical system of the exposure apparatus shown in FIG. 1.

FIG. 5 is a view showing the arrangement of an exposure apparatus in the second embodiment of the present invention.

FIG. 6 is a view showing the arrangement of an exposure apparatus in the third embodiment of the present invention.

FIGS. 7A to 7E are views for explaining details of the fact that an asymmetric blur occurs in an effective light source formed by an illumination optical system.

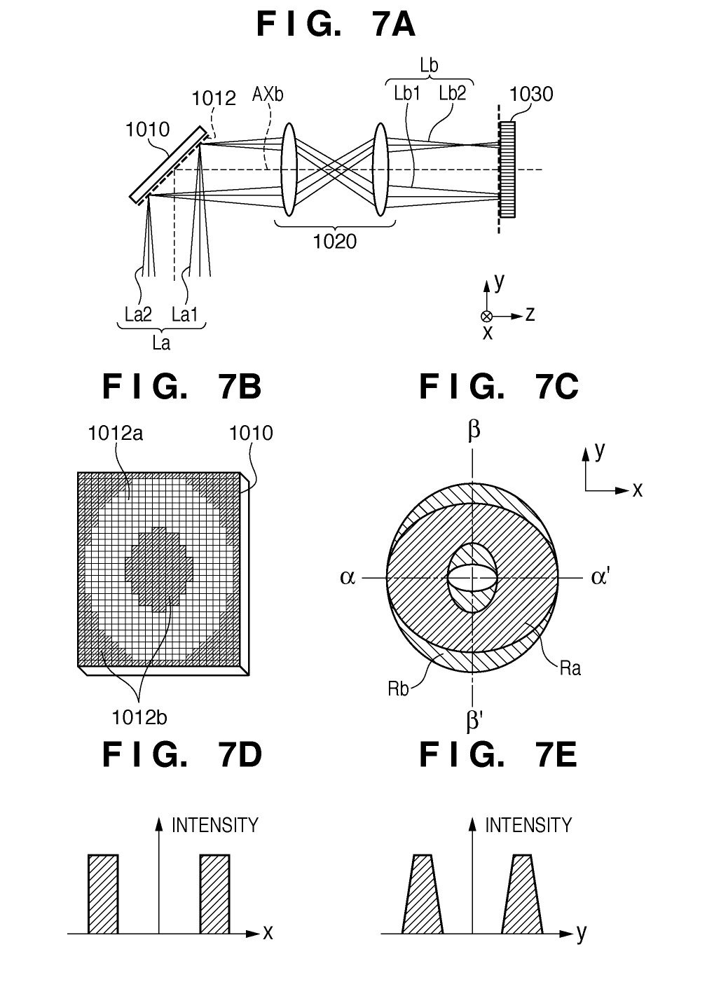

### DESCRIPTION OF THE EMBODIMENTS

Preferred embodiments of the present invention will be described below with reference to the accompanying drawings. Note that the same reference numerals denote the same members throughout the drawings, and a repetitive description thereof will not be given.

### First Embodiment

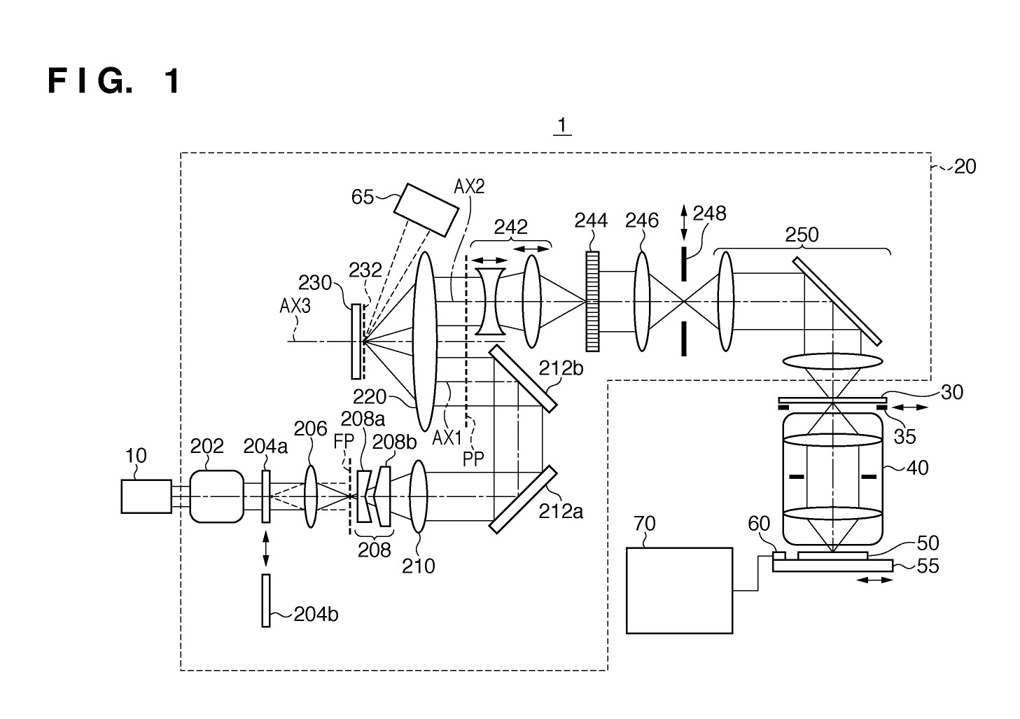

FIG. 1 is a view showing the arrangement of an exposure apparatus 1 in the first embodiment of the present invention. The exposure apparatus 1 is a projection exposure apparatus which transfers the pattern of a reticle onto a wafer by the step & scan scheme or the step & repeat scheme.

The exposure apparatus 1 includes an illumination optical system 20 which illuminates a reticle 30 with light from a light source 10, a reticle stage 35 which holds the reticle 30, a projection optical system 40 which projects the pattern of the reticle 30 onto a wafer 50, and a wafer stage 55 which holds the wafer 50. The exposure apparatus 1 also includes a first detection unit 60, a second detection unit 65, and a control unit 70.

A KrF excimer laser with a wavelength of about 248 nm or an ArF excimer laser with a wavelength of about 193 nm, for example, is used as the light source 10. However, the types and number of light sources 10 are not particularly limited.

In this embodiment, the illumination optical system 20 includes a beam shaping optical system 202, diffraction optical elements 204a and 204b, a condenser optical system 206, a prism 208, a condenser optical system 210, and deflecting mirrors 212a and 212b. The illumination optical system 20 also includes a condenser optical system (first optical system) 220, a mirror array optical element 230, a zoom optical system 242, a microlens array 244, a condenser optical system 246, a field stop 248, and an imaging optical system 250.

Light (nearly collimated light) emitted by the light source 10 is shaped into light with a predetermined size via the beam shaping optical system 202 having a known arrangement, and enters the diffraction optical element 204a or 204b. The diffraction optical elements 204a and 204b have different diffraction actions, and are switchably mounted on, for example, a turret (not shown). Light intensity distributions with various shapes such as a circular shape, an annular shape, and multipole shapes can be formed on a Fourier transform plane FP by switching the diffraction optical element to be positioned in the optical path of the illumination optical system 20.

The light emerging from the diffraction optical element 204a or 204b is focused on the Fourier transform plane FP via the condenser optical system 206. The diffraction optical elements 204a and 204b and the Fourier transform plane FP are made to have an optically Fourier transform relationship by the condenser optical system 206, and a light intensity distribution based on a diffraction action of the diffraction optical element 204a or 204b is formed on the Fourier transform plane FP.

The light intensity distribution formed on the Fourier transform plane FP has its shape adjusted by the prism 208, and is guided to the deflecting mirrors 212a and 212b via the condenser optical system 210. The prism 208 includes, for example, a first optical member 208a and a second optical member 208b, and is configured such that the interval between the first optical member 208a and the second optical member 208b can be adjusted. When the interval between the first optical member 208a and the second optical member 208b is sufficiently small, the prism 208 can be approximately regarded as a plane-parallel plate glass. Thus, the light intensity distribution formed on the Fourier transform plane FP enters the mirror array optical element 230 via the condenser optical system 210, deflecting mirrors 212a and 212b, and condenser optical system 220 while holding nearly similar figures. Also, the annular zone ratio (beam inner diameter/beam outer diameter) of the light which enters the mirror array optical element 230 can be adjusted by increasing the interval between the first optical member 208a and the second optical member 208b. The Fourier transform plane FP and the mirror array optical element 230 are made optically conjugate to each other by the condenser optical systems 210 and 220.

An optical system (second optical system) which includes the beam shaping optical system 202 to the deflecting mirror 212b, and is present on the light source side with respect to the condenser optical system 220 guides light from the light source 10 to the condenser optical system 220.

The mirror array optical element 230 is an optical element in which a plurality of mirror elements 232 having reflecting surfaces that reflect light from the light source 10 are two-dimensionally arrayed, and the angles of the plurality of mirror elements 232 can be independently controlled. In this embodiment, the mirror array optical element 230 is disposed near a plane optically conjugate to the pupil plane of the illumination optical system 20, and is used to adjust the shape of the effective light source.

A certain component of the light reflected by the mirror array optical element 230 enters the condenser optical system 220. In this manner, the condenser optical system 220 guides light from the light source 10 to the mirror array optical element 230, and receives light reflected by a predetermined mirror element 232, the angle of which is controlled to guide the light reflected by its reflecting surface to the reticle 30.

An optical system (third optical system) which includes the zoom optical system 242 to the imaging optical system 250, and is present on the reticle side with respect to the condenser optical system 220 receives the light from the condenser optical system 220. More specifically, light which is reflected by the mirror array optical element 230 and passes through the condenser optical system 220 is enlarged or reduced via the zoom optical system 242, and enters the microlens array 244. The microlens array 244 functions as an optical integrator, and can also be substituted by, for example, an optical rod. The incident surfaces of the microlens array 244 and the mirror array optical element 230 are made optically conjugate to each other via the condenser optical system 220 and zoom optical system 242.

The microlens array 244 is an optical element in which a plurality of microlenses are two-dimensionally arranged. The light incident on the microlens array 244 undergoes wavefront splitting and is focused on the rear focal plane of each microlens (the exit surface of the microlens array 244). A large number of secondary light sources are formed on the exit surface of the microlens array 244. These secondary light sources are optically conjugate to the pupil plane of the projection optical system 40. In this manner, the incident surface of the microlens array 244 is positioned near a plane optically conjugate to the pupil plane of the projection optical system 40. Hence, the shape of the effective light source can be adjusted by controlling the mirror array optical element 230 at a position optically conjugate to the incident surface of the microlens array 244.

The light emerging from the microlens array 244 is converged by the condenser optical system 246, and superposedly illuminates the field stop 248 at a position optically conjugate to the reticle 30 (wafer 50). The field stop 248 is a light-shielding member which defines the illumination region on the reticle 30 (the exposure region on the wafer 50). The field stop 248, for example, includes a plurality of light-shielding plates, and is configured such that an aperture shape corresponding to the illumination region can be formed by driving the plurality of light-shielding plates.

The imaging optical system 250 forms an image of (projects) the light beam having passed through the field stop 248 (that is, the aperture shape formed by the field stop 248) on the reticle 30.

The reticle 30 has a pattern to be formed on the wafer 50, and is held and driven by the reticle stage 35. Light diffracted by the reticle 30 is projected onto the wafer 50 via the projection optical system 40.

The reticle stage 35 supports the reticle 30, and drives it in the x-, y-, and z-axis directions and rotation directions about the respective axes using, for example, a linear motor.

The projection optical system 40 projects the pattern of the reticle 30 onto the wafer 50. A dioptric system, a catadioptric system, or a catoptric system can be used as the projection optical system 40.

The wafer 50 is a substrate onto which the pattern of the reticle 30 is projected (transferred). However, the wafer 50 can be substituted by a glass plate or another substrate. The wafer 50 is coated with a resist (photosensitive agent).

The wafer stage 55 supports the wafer 50, and drives it in the x-, y-, and z-axis directions and rotation directions about the respective axes using, for example, a linear motor, like the reticle stage 35.

The first detection unit 60 is disposed on the wafer stage 55, and detects the light intensity at each point on the wafer 50. The first detection unit 60 includes, for example, a pinhole plate having a pinhole and a CCD which detects the light having passed through the pinhole. The first detection unit 60 inputs a signal corresponding to the detected light intensity to the control unit 70.

The control unit 70 includes a CPU and memory, and controls the whole (operation) of the exposure apparatus 1. The control unit 70, for example, converts the light intensity detected by the first detection unit 60 into an effective light source, and compares the shape of the converted effective light source with that of a target effective light source. If the difference between the shape of the converted effective light source and that of the target effective light source falls outside a tolerance, the control unit 70 obtains settings of respective units of the illumination optical system 20, which are necessary to correct (adjust) the shape of the effective light source. The settings of respective units of the illumination optical system 20 include herein the angles of the plurality of mirror elements 232 which constitute the mirror array optical element 230, and the interval between the first optical member 208a and second optical member 208b which constitute the prism 208. The settings of respective units of the illumination optical system 20 also include, for example, switching of the diffraction optical element to be disposed in the optical path of the illumination optical system 20 (i.e., determination as to whether the diffraction optical element 204a or 204b is to be disposed), and driving of the zoom optical system 242. Based on the settings of respective units of the illumination optical system 20, the control unit 70 controls, for example, the angles of the plurality of mirror elements 232 which constitute the mirror array optical element 230, and driving of the zoom optical system 242.

The mirror array optical element 230 will be described in detail herein. In this embodiment, the angles of the plurality of mirror elements 232 which constitute the mirror array optical element 230 are controlled so that they assume at least two states: a first state and a second state. The first state means herein the state in which light reflected by the reflecting surface of the mirror element 232 impinges on the reticle 30 (that is, the state in which light reflected by that reflecting surface reaches the microlens array 244). Also, the second state means herein the state in which the light reflected by the reflecting surface of the mirror element 232 does not impinge on the reticle 30 (that is, the light reflected by that reflecting surface does not reach the microlens array 244). In this embodiment, light reflected by the reflecting surfaces of the mirror elements 232, the angles of which are controlled to assume the second state enters the second detection unit 65 with the same arrangement as the first detection unit 60. Hence, if the angles of all the mirror elements 232 which constitute the mirror array optical element 230 are controlled so that they assume the second state, the second detection unit 65 detects the intensity distribution of light which enters the mirror array optical element 230 (the light from the condenser optical system 220). However, the second detection unit 65 is not a constituent element indispensable for the exposure apparatus 1, and a diffuser for reducing stray light, for example, may be disposed in place of the second detection unit 65.

Light intensity distributions with various shapes can be freely extracted from the light incident on the mirror array optical element 230 by independently controlling the angles of the plurality of mirror elements 232 which constitute the mirror array optical element 230. That is, the effective light source can be adjusted using the mirror array optical element 230 to adjust a light intensity distribution which is roughly formed by, for example, the diffraction optical element 204a or 204b and prism 208.

Note that although the effective light source is easy to adjust in the illumination optical system 20 including the mirror array optical element 230, loss in light amount occurs because light is extracted from a roughly formed light intensity distribution. As a result, the time taken to expose the wafer 50 is prolonged, and this may degrade the productivity of semiconductor devices. In such a case, after the effective light source is optimized using the mirror array optical element 230, diffraction optical elements and a prism for forming the optimized effective light source can be newly manufactured. With this process, a certain cost and time are required to manufacture diffraction optical elements and a prism, but any loss in light amount that occurs upon extracting light by the mirror array optical element 230 is eliminated. This makes it possible to suppress degradation in productivity of semiconductor devices.

Also, when diffraction optical elements, a prism, etc., which form an optimized effective light source are newly manufactured, this obviates the need to extract light by the mirror array optical element 230. In such a case, the same function as a normal deflecting mirror can be implemented by controlling the angles of all the mirror elements 232 which constitute the mirror array optical element 230 so that they assume the first state.

However, as described above, the mirror array optical element 230 is an optical element in which the plurality of mirror elements 232 are two-dimensionally arrayed, so the filling ratio of the mirror elements 232 is not 100%. Also, diffraction by the surface structure of the mirror array optical element 230, and absorption and scattering by the reflecting surfaces of the mirror elements 232, for example, often occur. Therefore, even if the mirror array optical element 230 functions as a deflecting mirror, it has a light use efficiency poorer than a normal deflecting mirror. As a result, the time taken to expose the wafer 50 is prolonged, and this may degrade the productivity of semiconductor devices. In such a case, the mirror array optical element 230 can be switchable to/from a normal deflecting mirror. More specifically, an optical element switching unit including a stocker which stocks optical elements, and a hand which switches the optical elements from one to another is disposed, and switches the mirror array optical element 230 and the deflecting mirror from one to the other. If the mirror array optical element 230 need not adjust the effective light source, the use efficiency of light from the light source 10 can be improved by switching to a normal deflecting mirror with high light use efficiency.

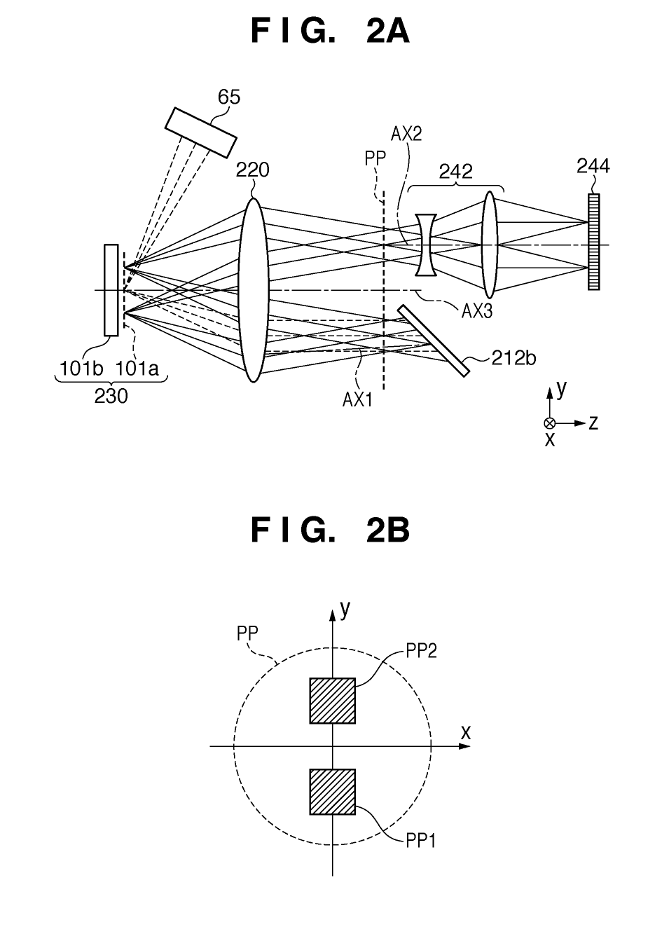

FIG. 2A is a partial enlarged view of the illumination optical system 20 from the deflecting mirror 212b to the microlens array 244. Although the condenser optical system 220 is shown as a single lens in FIG. 2A, it generally includes a plurality of lenses in practice from the viewpoint of, for example, aberration correction. Also, the condenser optical system 220 may include not only lenses but also mirrors. As shown in FIG. 2A, an optical axis AX1 of the deflecting mirror 212b (the exit-side optical axis of the second optical system) is parallel to an optical axis AX3 of the mirror elements 232, the angles of which are controlled to assume the first state, and shifts from the optical axis AX3 (the optical axis AX1 is spaced apart from the optical axis AX3 in the −y-axis direction in this embodiment). Also, an optical axis AX2 of the zoom optical system 242 (the incident-side optical axis of the third optical system) is parallel to the optical axis AX3 of the mirror elements 232, the angles of which are controlled to assume the first state, and shifts from the optical axis AX3 (the optical axis AX2 is spaced apart from the optical axis AX3 in the +y-axis direction in this embodiment). Moreover, the reflecting surfaces of the mirror elements 232, the angles of which are controlled to assume the first state are perpendicular to the optical axis AX1 of the deflecting mirror 212b and the optical axis AX2 of the zoom optical system 242.

A plane PP is positioned near the pupil plane of the condenser optical system 220 when the reflecting surfaces of the mirror elements 232, the angles of which are controlled to assume the first state are set as its object planes. The light deflected by the deflecting mirror 212b is converged by the condenser optical system 220 upon passing through the plane PP, and enters the mirror array optical element 230. Light reflected by the reflecting surfaces of mirror elements 232, the angles of which are controlled to assume the first state, among the plurality of mirror elements 232 which constitute the mirror array optical element 230 is converged by the condenser optical system 220, and passes through the plane PP again. On the other hand, light reflected by the reflecting surfaces of mirror elements 232, the angles of which are controlled to assume the second state, among the plurality of mirror elements 232 which constitute the mirror array optical element 230 is guided to the second detection unit 65, as described above.

The angles of the mirror elements 232 in the first state desirably make them parallel to a substrate in which the mirror elements 232 are arrayed (that is, desirably are 0° with respect to the substrate). Thus, when the angles of all of the plurality of mirror elements 232 are controlled to assume the first state, the reflecting surfaces of the plurality of mirror elements 232 belong to one flat plane. As a result, a light intensity distribution formed on the incident surface of the microlens array 244 can be prevented from being distorted.

The mirror array optical element 230 (the reflecting surfaces of the mirror elements 232, the angles of which are controlled to assume the first state), and the incident surface of the microlens array 244, are made optically conjugate to each other by the condenser optical system 220 and zoom optical system 242. Hence, the imaging magnification can be changed by adjusting the intervals between lenses which constitute the zoom optical system 242. In this way, a light intensity distribution formed (adjusted) by the mirror array optical element 230 is enlarged or reduced by the zoom optical system 242, and forms an image on the incident surface of the microlens array 244.

FIG. 2B is a view showing a region through which the light which enters the condenser optical system 220 passes, and that through which the light which emerges from the condenser optical system 220 passes, in the plane PP. The light deflected by the deflecting mirror 212b passes through a first region PP1 in the plane PP. The light having passed through the first region PP1 is converged by the condenser optical system 220, and enters the mirror array optical element 230. Light reflected by the reflecting surfaces of mirror elements 232, the angles of which are controlled to assume the first state, among the plurality of mirror elements 232 which constitute the mirror array optical element 230 is converged by the condenser optical system 220, and passes through a second region PP2 in the plane PP. In this manner, the light which enters the condenser optical system 220 (the light before entrance into the mirror array optical element 230), and the light which emerges from the condenser optical system 220 (the light after entrance into the mirror array optical element 230) pass through different regions in the plane PP.

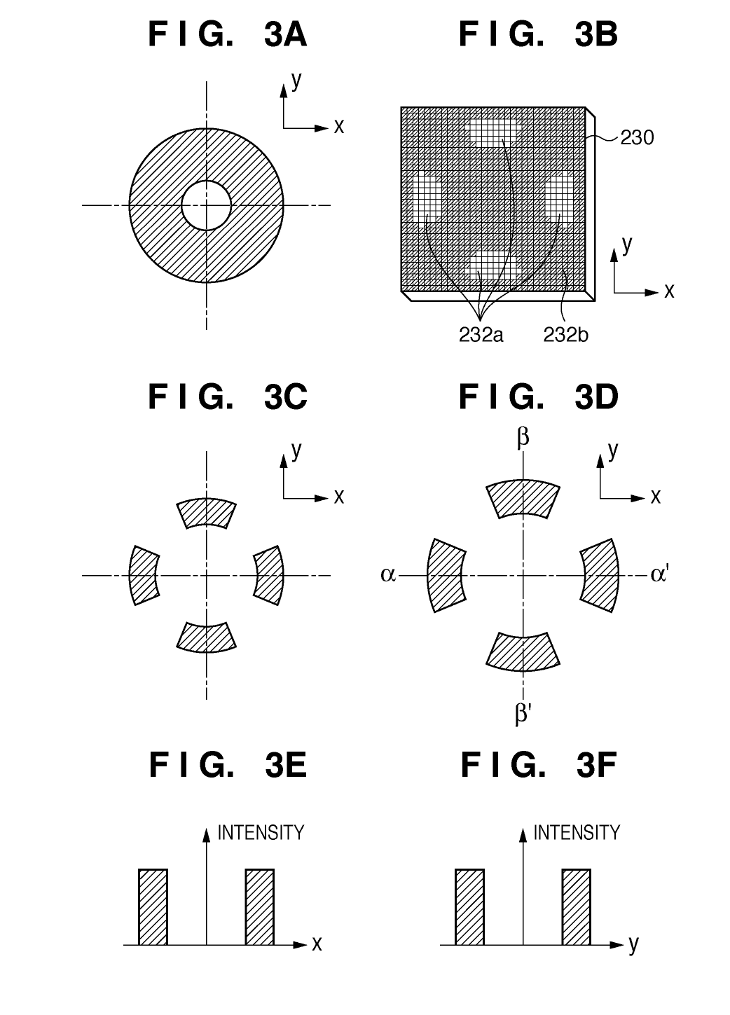

FIG. 3A shows the intensity distribution of light which enters the mirror array optical element 230. The light intensity distribution shown in FIG. 3A can be changed to some extent by switching the diffraction optical elements 204a and 204b from one to the other, or adjusting the interval between the first optical member 208a and second optical member 208b which constitute the prism 208.

FIG. 3B is a view showing the outer appearance of the mirror array optical element 230. In FIG. 3B, reference numerals 232a denote mirror elements, the angles of which are controlled to assume the first state; and reference numeral 232b denotes a mirror element, the angle of which is controlled to assume the second state. The mirror array optical element 230 forms a quadrupole light intensity distribution. The same effect as obtained by disposing a quadrupole stop on the pupil plane of the illumination optical system 20 can be obtained by controlling the plurality of mirror elements 232 to assume the first or second state, as shown in FIG. 3B.

FIG. 3C is a view showing the intensity distribution of light reflected by the reflecting surfaces of the mirror elements 232a when the mirror array optical element 230 is controlled to the state shown in FIG. 3B. As can be seen by referring to FIG. 3C, the mirror array optical element 230 extracts a quadrupole light intensity distribution from the annular intensity distribution of light which enters the mirror array optical element 230.

Light reflected by the reflecting surfaces of the mirror elements 232a among the plurality of mirror elements 232 which constitute the mirror array optical element 230 is converged by the condenser optical system 220, is enlarged or reduced by the zoom optical system 242, and enters the microlens array 244. FIG. 3D is a view showing a light intensity distribution (effective light source) formed on the incident surface of the microlens array 244.

FIGS. 3E and 3F are graphs taken along lines α-α′ and β-β′, respectively, in the light intensity distribution shown in FIG. 3D. In this embodiment, the optical axis AX1 of the deflecting mirror 212b and the optical axis AX2 of the zoom optical system 242 are parallel to the optical axis AX3 of the mirror elements 232, and shift from the optical axis AX3, as described earlier. Therefore, the focal position of the light from the mirror array optical element 230 remains the same regardless of its position in the x- and y-axis directions, so the light intensity distribution has no blur along the x- and y-axes, respectively, and has a rectangular cross-section.

In this manner, in this embodiment, since no asymmetry occurs in the light intensity distribution (effective light source) in the x- and y-axis directions, an effective light source with a complex shape can be formed with high accuracy. Hence, the exposure apparatus 1 can provide high-quality devices (for example, a semiconductor device, an LCD device, an image sensing device (for example, a CCD), and a thin film magnetic head) with a high throughput and good economical efficiency. These devices are fabricated by a step of exposing a substrate (for example, a wafer or a glass plate) coated with a photoresist (photosensitive agent) using the exposure apparatus 1, a step of developing the exposed substrate, and subsequent known steps.

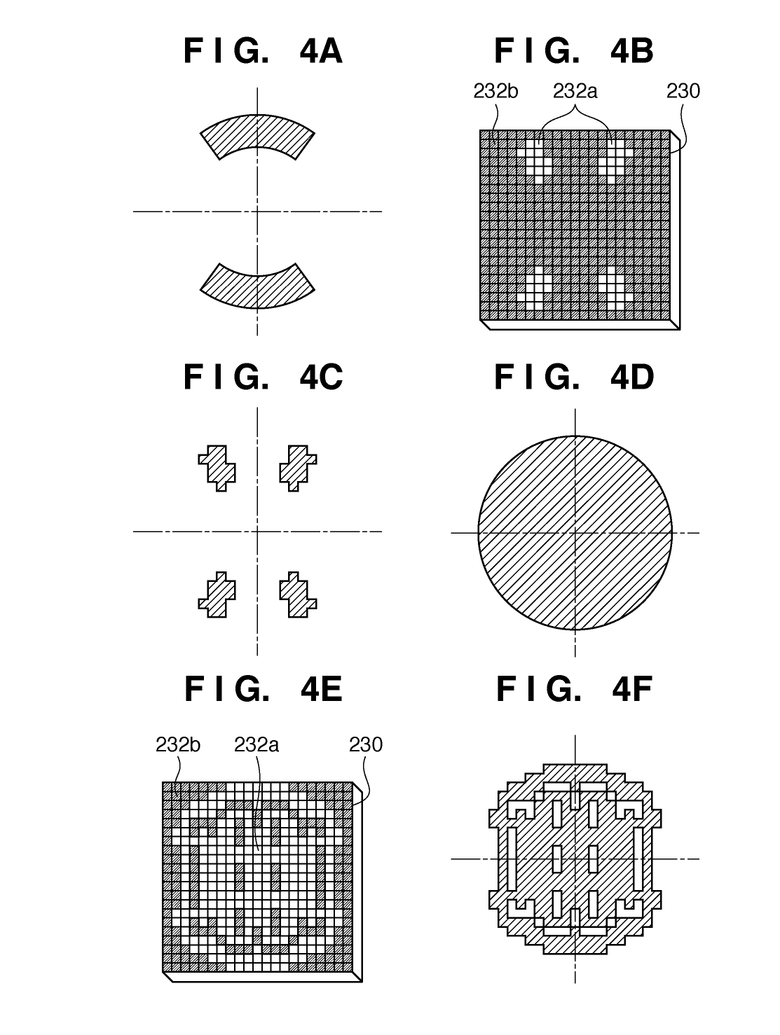

Note that a light intensity distribution (effective light source) which can be formed by the illumination optical system 20 is not limited to a quadrupole shape, and light intensity distributions (effective light sources) with various shapes can be formed, as shown in FIGS. 4A to 4F.

FIGS. 4A and 4D are views showing the intensity distributions of light which enters the mirror array optical element 230, in which FIG. 4A shows a dipole light intensity distribution, and FIG. 4D shows a circular light intensity distribution.

FIGS. 4B and 4E are views showing the outer appearances of the mirror array optical element 230. In FIGS. 4B and 4E, reference numerals 232a denote mirror elements, the angles of which are controlled to assume the first state; and reference numeral 232b denotes a mirror element, the angle of which is controlled to assume the second state. The mirror array optical element 230 forms a quadrupole light intensity distribution in FIG. 4B, and a light intensity distribution with a more complex shape in FIG. 4E.

FIG. 4C is a view showing a quadrupole light intensity distribution (effective light source) formed on the incident surface of the microlens array 244 when the mirror array optical element 230 is controlled to the state shown in FIG. 4B. FIG. 4F is a view showing a light intensity distribution (effective light source) with a more complex shape, which is formed on the incident surface of the microlens array 244 when the mirror array optical element 230 is controlled to the state shown in FIG. 4E. As can be seen by referring to FIGS. 4C and 4F, no asymmetry occurs in the light intensity distribution (effective light source) in the x- and y-axis directions.

### Second Embodiment

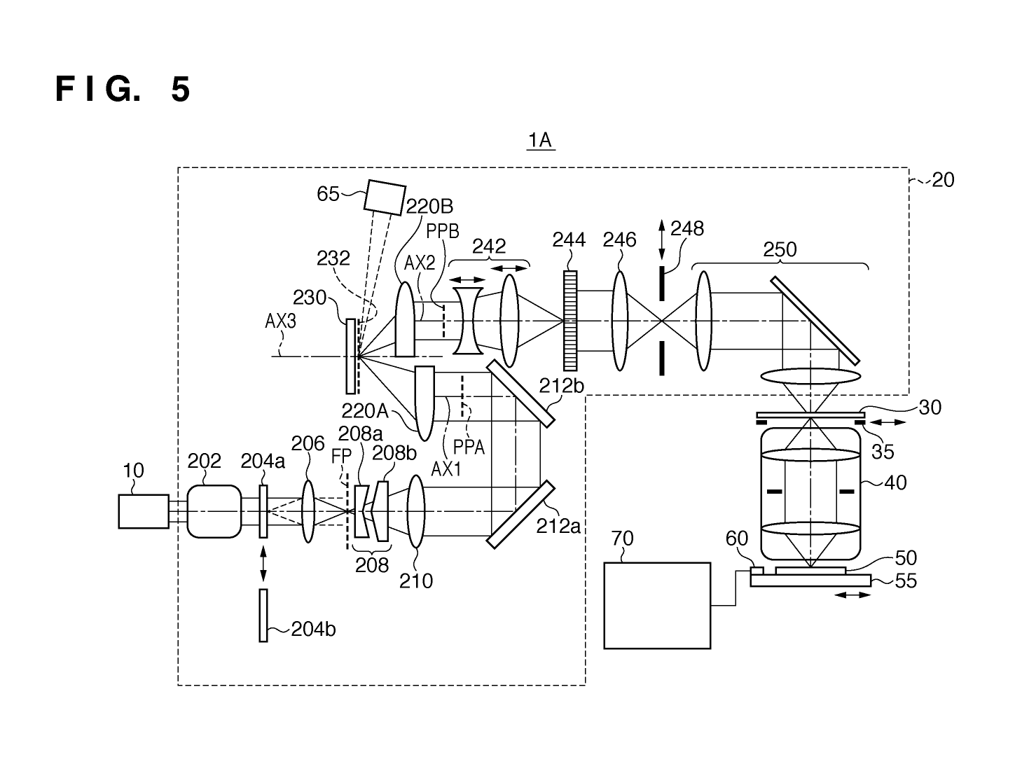

FIG. 5 is a view showing the arrangement of an exposure apparatus 1A in the second embodiment of the present invention. The exposure apparatus 1A has basically the same arrangement as the exposure apparatus 1. However, the exposure apparatus 1A includes a condenser optical system 220A on the incident side of a mirror array optical element 230, and a condenser optical system 220B on the exit side of the mirror array optical element 230, in place of the condenser optical system 220. An optical system (third optical system) which includes a beam shaping optical system 202 to a deflecting mirror 212b, and is present on the light source side with respect to the condenser optical system (first optical system) 220A guides light from a light source 10 to the condenser optical system 220A. Also, an optical system (fourth optical system) which includes a zoom optical system 242 to an imaging optical system 250, and is present on the reticle side with respect to the condenser optical system (second optical system) 220B receives the light from the condenser optical system 220B.

Both the condenser optical systems 220A and 220B are decentered with respect to an optical axis AX3 of mirror elements 232, the angles of which are controlled to assume the first state. Therefore, an optical axis AX1 of the deflecting mirror 212b (the exit-side optical axis of the third optical system), and an optical axis AX2 of the zoom optical system 242 (the incident-side optical axis of the fourth optical system) are parallel to the optical axis AX3 of the mirror elements 232, the angles of which are controlled to assume the first state. Also, the optical axis AX1 of the deflecting mirror 212b and the optical axis AX2 of the zoom optical system 242 are spaced apart from the optical axis AX3. Therefore, in the second embodiment as well, the focal position of the light from the mirror array optical element 230 remains the same regardless of its position in the x- and y-axis directions. As a result, no asymmetry occurs in the light intensity distribution (effective light source) in the x- and y-axis directions.

Although each of the condenser optical systems 220A and 220B is shown as a single lens in FIG. 5, it generally includes a plurality of lenses in practice from the viewpoint of, for example, aberration correction. Also, although the condenser optical systems 220A and 220B have different focal lengths, they may have the same focal length.

A plane PPA is positioned near the pupil plane of the condenser optical system 220A when the reflecting surfaces of the mirror elements 232, the angles of which are controlled to assume the first state are set as its object planes. The light deflected by the deflecting mirror 212b is converged by the condenser optical system 220 upon passing through the plane PPA, and enters the mirror array optical element 230.

A plane PPB is positioned near the pupil plane of the condenser optical system 220B when the reflecting surfaces of the mirror elements 232, the angles of which are controlled to assume the first state are set as its object planes. Light reflected by the reflecting surfaces of mirror elements 232, the angles of which are controlled to assume the first state, among the plurality of mirror elements 232 which constitute the mirror array optical element 230 is converged by the condenser optical system 220B, and passes through the plane PPB. On the other hand, light reflected by the reflecting surfaces of mirror elements 232, the angles of which are controlled to assume the second state, among the plurality of mirror elements 232 which constitute the mirror array optical element 230 is guided to a second detection unit 65.

The mirror array optical element 230 (the reflecting surfaces of the mirror elements 232, the angles of which are controlled to assume the first state), and the incident surface of a microlens array 244 are made optically conjugate to each other by the condenser optical system 220B and zoom optical system 242. Hence, the imaging magnification can be changed by adjusting the intervals between lenses which constitute the zoom optical system 242. In this way, a light intensity distribution formed (adjusted) by the mirror array optical element 230 is enlarged or reduced by the zoom optical system 242, and forms an image on the incident surface of the microlens array 244.

In this manner, even if the two condenser optical systems 220A and 220B substitute for the condenser optical system 220, no asymmetry occurs in the light intensity distribution (effective light source) in the x- and y-axis directions, so an effective light source with a complex shape can be formed with high accuracy.

### Third Embodiment

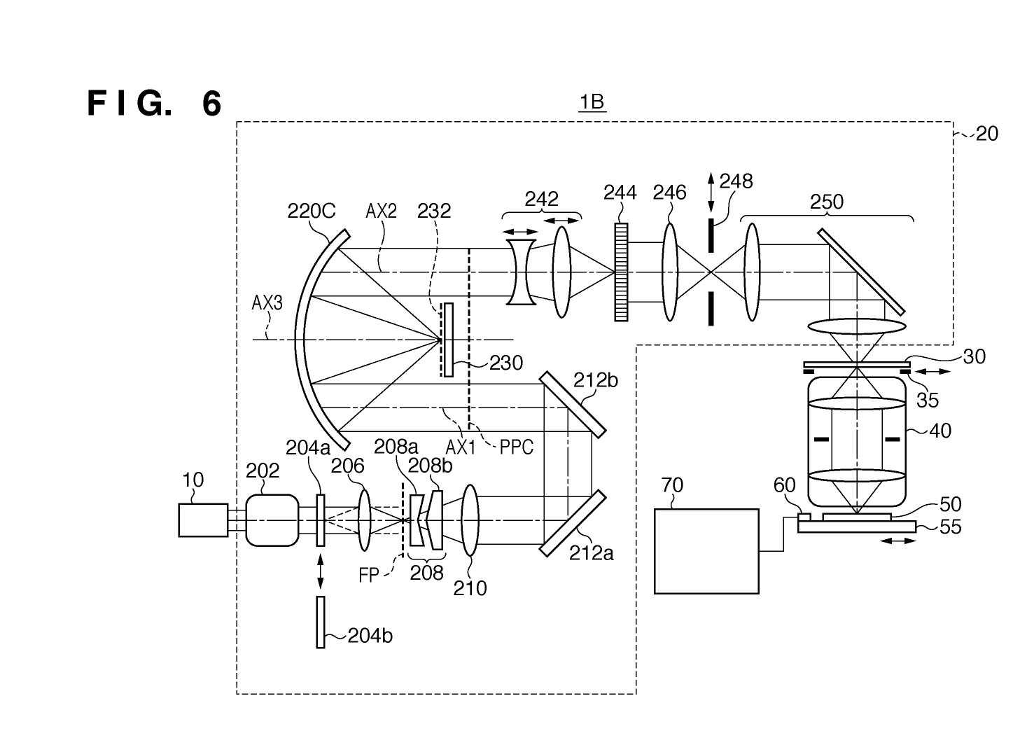

FIG. 6 is a view showing the arrangement of an exposure apparatus 1B in the third embodiment of the present invention. The exposure apparatus 1B has basically the same arrangement as the exposure apparatus 1. However, the exposure apparatus 1B includes a reflective (mirror type) condenser optical system (first optical system) 220C, in place of the condenser optical system 220. An optical system (second optical system) which includes a beam shaping optical system 202 to a deflecting mirror 212b, and is present on the light source side with respect to the condenser optical system 220C guides light from a light source 10 to the condenser optical system 220C. Also, an optical system (third optical system) which includes a zoom optical system 242 to an imaging optical system 250, and is present on the reticle side with respect to the condenser optical system 220C receives the light from the condenser optical system 220C.

An optical axis AX1 of the deflecting mirror 212b (the exit-side optical axis of the second optical system), and an optical axis AX2 of the zoom optical system 242 (the incident-side optical axis of the third optical system) are parallel to an optical axis AX3 of mirror elements 232, the angles of which are controlled to the first state. Also, the optical axis AX1 of the deflecting mirror 212b and the optical axis AX2 of the zoom optical system 242 are spaced apart from the optical axis AX3. Therefore, the focal position of the light from a mirror array optical element 230 remains the same regardless of its position in the x- and y-axis directions. As a result, in the third embodiment as well, no asymmetry occurs in the light intensity distribution (effective light source) in the x- and y-axis directions.

Although the condenser optical system 220C is shown as a single mirror in FIG. 6, it generally is a catadioptric system including, for example, a plurality of lenses in practice from the viewpoint of, for example, aberration correction. Also, the condenser optical system 220C may have an aspherical reflecting surface such as a paraboloidal surface again from the viewpoint of aberration correction.

A plane PPC is positioned near the pupil plane of the condenser optical system 220C when the reflecting surfaces of the mirror elements 232, the angles of which are controlled to assume the first state are set as its object planes. The light deflected by the deflecting mirror 212b is converged by the condenser optical system 220C upon passing through the plane PPC, and enters the mirror array optical element 230. Light reflected by the reflecting surfaces of mirror elements 232, the angles of which are controlled to assume the first state, among the plurality of mirror elements 232 which constitute the mirror array optical element 230 is converged by the condenser optical system 220C, and passes through the plane PPC. In this manner, the light which enters the condenser optical system 220C (the light before entrance into the mirror array optical element 230), and the light which emerges from the condenser optical system 220C (the light after entrance into the mirror array optical element 230) pass through different regions in the plane PPC. On the other hand, light reflected by the reflecting surfaces of mirror elements 232, the angles of which are controlled to assume the second state, among the plurality of mirror elements 232 which constitute the mirror array optical element 230 is guided to a second detection unit (not shown).

The mirror array optical element 230 (the reflecting surfaces of the mirror elements 232, the angles of which are controlled to assume the first state), and the incident surface of a microlens array 244 are made optically conjugate to each other by the condenser optical system 220 and zoom optical system 242. Hence, the imaging magnification can be changed by adjusting the intervals between lenses which constitute the zoom optical system 242. In this way, a light intensity distribution formed (adjusted) by the mirror array optical element 230 is enlarged or reduced by the zoom optical system 242, and forms an image on the incident surface of the microlens array 244.

In this manner, even if the condenser optical system 220C substitutes for the condenser optical system 220, no asymmetry occurs in the light intensity distribution (effective light source) in the x- and y-axis directions, so an effective light source with a complex shape can be formed with high accuracy.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2009-262370 filed on Nov. 17, 2009, which is hereby incorporated by reference herein in its entirety.

What is claimed is:

1. An exposure apparatus comprising:
an illumination optical system configured
to illuminate a reticle with light from a light source; and
a projection optical system configured to project a pattern of the reticle onto a substrate,
said illumination optical system including
a mirror array optical element including a plurality of mirror elements having reflecting surfaces which reflect the light from the light source, said plurality of mirror elements having angles that can be independently controlled with respect to the light from the light source,
a first optical system configured to guide the light from the light source to said mirror array optical element, and receive light reflected by a predetermined mirror element, an angle of which is controlled to guide the light reflected by the reflecting surface to the reticle, among said plurality of mirror elements,
a second optical system which is present on a side of the light source with respect to said first optical system, and is configured to guide the light from the light source to said first optical system, and
a third optical system which is present on a side of the reticle with respect to said first optical system, and is configured to receive the light from said first optical system,
wherein an exit-side optical axis of said second optical system and an incident-side optical axis of said third optical system are parallel to an optical axis of the predetermined mirror element, and are spaced apart from the optical axis of the predetermined mirror element, and
a reflecting surface of the predetermined mirror element is perpendicular to the exit-side optical axis of said second optical system and the incident-side optical axis of said third optical system.

2. The apparatus according to claim 1, wherein
the angles of said plurality of mirror elements are controlled so that said plurality of mirror elements assume at least two states: a first state in which light reflected by the reflecting surface impinges on the reticle, and a second state in which the light reflected by the reflecting surface does not impinge on the reticle, and
the reflecting surfaces of said plurality of mirror elements belong to one flat plane when the angles of all of said plurality of mirror elements are controlled so that said plurality of mirror elements assume the first state.

3. The apparatus according to claim 1, wherein the light which enters said first optical system and the light which emerges from said first optical system pass through different regions in a pupil plane of said first optical system when said mirror array optical element is set as an object plane thereof.

4. The apparatus according to claim 1, wherein said first optical system includes a reflective optical system configured to reflect the light from the light source.

5. An exposure apparatus comprising:
an illumination optical system configured to illuminate a reticle with light from a light source; and
a projection optical system configured to project a pattern of the reticle onto a substrate,
said illumination optical system including
a mirror array optical element including a plurality of mirror elements having reflecting surfaces which reflect the light from the light source, said plurality of mirror elements having angles that can be independently controlled with respect to the light from the light source,
a first optical system configured to guide the light from the light source to said mirror array optical element,
a second optical system configured to receive light reflected by a predetermined mirror element, an angle of which is controlled to guide the light reflected by the reflecting surface to the reticle, among said plurality of mirror elements,
a third optical system which is present on a side of the light source with respect to said first optical system, and is configured to guide the light from the light source to said first optical system, and
a fourth optical system which is present on a side of the reticle with respect to said second optical system, and is configured to receive the light from said second optical system,
wherein an exit-side optical axis of said third optical system and an incident-side optical axis of said fourth optical system are parallel to an optical axis of the predetermined mirror element, and are spaced apart from the optical axis of the predetermined mirror element, and
a reflecting surface of the predetermined mirror element is perpendicular to the exit-side optical axis of said third optical system and the incident-side optical axis of said fourth optical system.

6. A device fabrication method comprising steps of:
exposing a substrate using an exposure apparatus; and
performing a development process for the substrate exposed,
wherein the exposure apparatus includes:
an illumination optical system configured to illuminate a reticle with light from a light source; and
a projection optical system configured to project a pattern of the reticle onto the substrate,
said illumination optical system including
a mirror array optical element including a plurality of mirror elements having reflecting surfaces which reflect the light from the light source, said plurality of mirror elements having angles that can be independently controlled with respect to the light from the light source,
a first optical system configured to guide the light from the light source to said mirror array optical element, and receive light reflected by a predetermined mirror element, an angle of which is controlled to guide the light reflected by the reflecting surface to the reticle, among said plurality of mirror elements,
a second optical system which is present on a side of the light source with respect to said first optical system, and is configured to guide the light from the light source to said first optical system, and
a third optical system which is present on a side of the reticle with respect to said first optical system, and is configured to receive the light from said first optical system,
wherein an exit-side optical axis of said second optical system and an incident-side optical axis of said third optical system are parallel to an optical axis of the predetermined mirror element, and are spaced apart from the optical axis of the predetermined mirror element, and
a reflecting surface of the predetermined mirror element is perpendicular to the exit-side optical axis of said second optical system and the incident-side optical axis of said third optical system.

7. A device fabrication method comprising steps of:
exposing a substrate using an exposure apparatus; and
performing a development process for the substrate exposed,
wherein the exposure apparatus includes:
an illumination optical system configured
to illuminate a reticle with light from a light source; and
a projection optical system configured to project a pattern of the reticle onto the substrate,
said illumination optical system including
a mirror array optical element including a plurality of mirror elements having reflecting surfaces which reflect the light from the light source, said plurality of mirror elements having angles that can be independently controlled with respect to the light from the light source,
a first optical system configured to guide the light from the light source to said mirror array optical element,
a second optical system configured to receive light reflected by a predetermined mirror element, an angle of which is controlled to guide the light reflected by the reflecting surface to the reticle, among said plurality of mirror elements,
a third optical system which is present on a side of the light source with respect to said first optical system, and is configured to guide the light from the light source to said first optical system, and
a fourth optical system which is present on a side of the reticle with respect to said second optical system, and is configured to receive the light from said second optical system,
wherein an exit-side optical axis of said third optical system and an incident-side optical axis of said fourth optical system are parallel to an optical axis of the predetermined mirror element, and are spaced apart from the optical axis of the predetermined mirror element, and
a reflecting surface of the predetermined mirror element is perpendicular to the exit-side optical axis of said third optical system and the incident-side optical axis of said fourth optical system.
